(19) United States
(12) Patent Application Publication
(10) Pub. No.: US 2023/0223068 A1
(43) Pub. Date: Jul. 13, 2023

(54) FLASH MEMORY MANAGEMENT DEVICE AND FLASH MEMORY MANAGEMENT METHOD

(71) Applicant: Mitsubishi Electric Corporation, Tokyo (JP)

(72) Inventors: Masahiko KATAYAMA, Tokyo (JP); Nariaki TAKEHARA, Tokyo (JP)

(73) Assignee: Mitsubishi Electric Corporation, Tokyo (JP)

(21) Appl. No.: 18/009,886

(22) PCT Filed: Oct. 28, 2020
(86) PCT No.: PCT/JP2020/040365

§ 371 Date: Dec. 12, 2022

(51) Int. Cl. G11C 11/406; G11C 11/4096

(52) U.S. Cl. CPC G11C 11/40622; G11C 11/40626; G11C 11/4096

(57) ABSTRACT

A flash memory lifespan is increased, using a simple process, while restricting an increase in cost. A flash memory management device includes a flash memory having data retaining areas, which retain data, and short-lived areas, which have the same cell structure as the data retaining areas and data retaining properties inferior to those of the data retaining areas, wherein data of the short-lived areas are confirmed by a controller, and data retained in the data retaining areas are refreshed in accordance with the confirmed data of the short-lived areas.

### TECHNICAL FIELD

The present application relates to the field of a flash memory management device and a flash memory management method.

### BACKGROUND ART

A non-volatile flash memory (a NOR flash memory, a NAND flash memory, or the like) stores data by accumulating an electrical charge in a floating gate of a cell. The electrical charge accumulated in the floating gate of each cell is lost in accompaniment to an elapse of time, because of which an error occurs in the data. A time until an error occurs in the data due to the electrical charge being lost is called a data retention time.

A non-volatile flash memory data retention time is temperature dependent, with the data retention time being shorter the higher the temperature. A storage device mounted in vehicle-mounted equipment has a short data retention time compared with that of a storage device used at room temperature.

Also, the data retention time is dependent on the number of rewrites, with the data retention time being shorter the greater the number of rewrites.

Technology such that a cell with a short data retention time is added to a flash ROM (read-only memory), and data are rewritten based on a result of referring to the cell, is disclosed in, for example, Patent Literature 1.

Also, technology such that a time for which data stored in a flash ROM can be retained is predicted based on the number of writes, the temperature, or the like of the flash ROM, and a rewriting of the data stored in the flash ROM is carried out before the time for which the data can be retained elapses, is disclosed in, for example, Patent Literature 2.

### CITATION LIST

### Patent Literature

Patent Literature 1: JP-A-2000-251483

Patent Literature 2: JP-A-2009-003843

### SUMMARY OF INVENTION

### Technical Problem

However, the technology disclosed in Patent Literature 1 has a problem in that a common flash ROM does not have a cell with a short data retention time, and adding a cell with a short data retention time leads to an increase in cost. Also, the technology disclosed in Patent Literature 2 has a problem in that the number of rewrites, the temperature, and an interval between writes need to be recorded every time a write is carried out, and processing becomes complicated.

The present application has been made to solve the above problem and an object of the present application is to increase a flash memory lifespan, using a simple process, while restricting an increase in cost.

### Solution to Problem

A flash memory management device disclosed in the present application includes a flash memory used as a data retaining device and a control unit that manages the flash memory, wherein the flash memory has data retaining areas, which retain data, and short-lived areas, which have the same cell structure as the data retaining areas and data retaining properties inferior to those of the data retaining areas, and the control unit confirms data of the short-lived areas, and refreshes data retained in the data retaining areas in accordance with the confirmed data of the short-lived areas.

### Advantageous Effects of Invention

According to the flash memory management device disclosed in the present application, a flash memory lifespan can be increased, using a simple process, while restricting an increase in cost.

### BRIEF DESCRIPTION OF DRAWINGS

FIG. 1 is a configuration drawing of a vehicle-mounted system in which a flash memory management device according to a first embodiment is used.

FIG. 2 is a drawing showing a flow of an initial write into a flash memory in the flash memory management device according to the first embodiment.

FIG. 3A is a flow diagram illustrating an operation of a control unit in the flash memory management device according to the first embodiment.

FIG. 3B is a flow diagram illustrating an operation of the control unit in the flash memory management device according to the first embodiment.

FIG. 4 is a drawing illustrating a disposition of the flash memory and the control unit of the flash memory management device according to a second embodiment.

### DESCRIPTION OF EMBODIMENTS

Hereafter, embodiments of a flash memory management device and a flash memory management method according to the present application will be described using the drawings. In the drawings, identical reference signs indicate identical or corresponding portions.

### First Embodiment

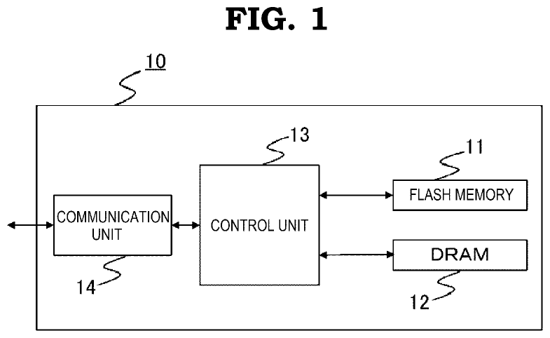

FIG. 1 is a configuration drawing of a vehicle-mounted system in which a flash memory management device according to a first embodiment is used. In FIG. 1, reference sign 10 indicates a flash memory management device, and the flash memory management device 10 is configured to include a flash memory 11, a data storing RAM (random-access memory), for example, a dynamic random-access memory (hereafter called a DRAM) 12, a control unit 13, and a communication unit 14.

The flash memory 11 is a non-volatile flash memory, for example, a NAND-type flash memory, and stores data and the like compiled based on a program such as an OS (operating system), a user, or an execution of software. The DRAM 12 stores a program or data read from the flash memory 11. Also, the DRAM 12 is used as storage of a program executed by the control unit 13, or as a work area.

The control unit 13 is, for example, a CPU (central processing unit), manages the flash memory 11, and controls the whole of the flash memory management device 10. In order to do so, the control unit 13 successively executes command codes placed in the DRAM 12, controls access to the flash memory 11, and carries out communication with an exterior of the flash memory management device 10 via the communication unit 14. Also, the control unit 13 confirms data of a short-lived area, to be described hereafter, detects a lifespan of a data retaining area, to be described hereafter, in accordance with the confirmed data, and refreshes the data.

The communication unit 14 executes communication with the exterior of the flash memory management device 10 with, for example, a CAN (controller area network), Ethernet (registered trademark), a SATA (serial advanced technology attachment), or an MMC (multimedia card interface) being used.

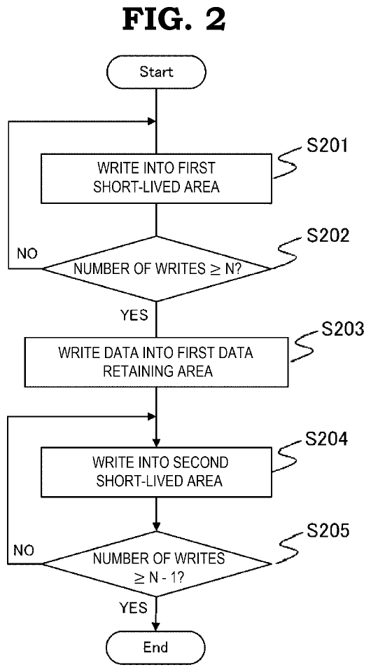

FIG. 2 is a drawing showing a flow of an initial write into the flash memory 11. An initial write into the flash memory 11 may be either off-board (before mounting on a substrate) or on-board (after mounting on a substrate).

The flash memory 11 has a multiple of data retaining areas for each write frequency and timing. For example, a first data retaining area has a program executed by the control unit 13, and a second data retaining area has, for example, data relating to a result of an axis adjustment that orients an axial line in a correct direction when millimeter wave radar or a camera having the flash memory management device 10 is attached to a vehicle, and the flash memory 11 has a short-lived area corresponding to each data retaining area. The short-lived area corresponding to each data retaining area has a cell structure the same as that of the data retaining area, and has data retaining properties inferior to those of the data retaining area.

The aforementioned short-lived area is configured of a multiple of cells, and in the case of, for example, a NAND-type flash memory, may be configured of units called pages.

In the flow of FIG. 2, a predetermined number (N, wherein N≥2) of data writes into a first short-lived area are repeated in the initial write (step S201 and step S202). When doing so, the written data are data such that electrons are injected into the cells of the flash memory 11, and in the case of, for example, an SLC (single level cell) NAND-type flash memory, electrons are injected into the cells of the flash memory 11 by writing data 0, because of which 0 is written into all the cells of the short-lived area.

Subsequently, data (a program executed by the control unit 13) are written into the first data retaining area (step S203).

Subsequently, a predetermined number (N−1) of writes of the data (the program executed by the control unit 13) into a second short-lived area are repeated (step S204 and step S205). When doing so, the written data are data such that electrons are injected into the cells of the flash memory 11.

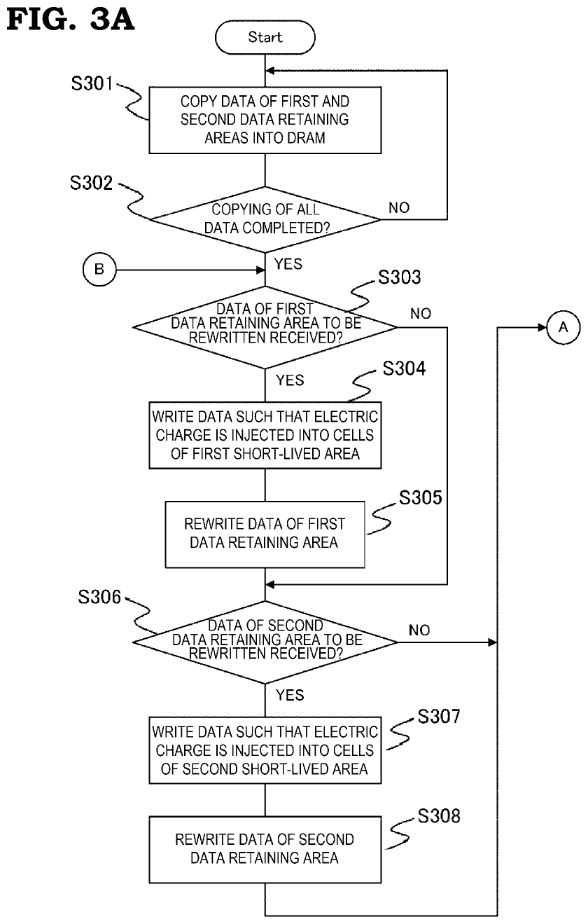

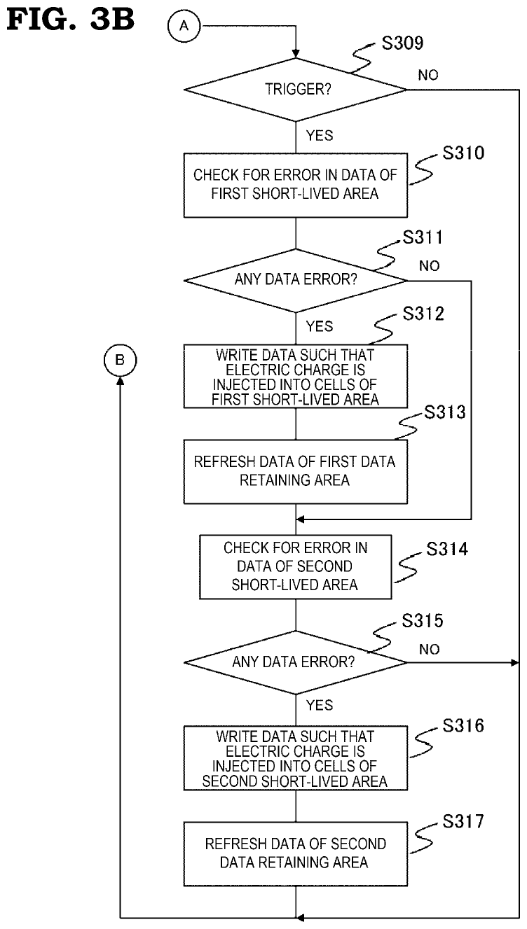

FIG. 3A and FIG. 3B are flow diagrams illustrating an operation of the control unit 13. In the flow of FIG. 3A and FIG. 3B, firstly, the control unit 13 reads data from the flash memory 11, and copies the data into the DRAM 12 (step S301 to step S302). Subsequently, the control unit 13 operates using a program copied into the DRAM 12 (data of the first data retaining area).

Next, it is confirmed via the communication unit 14 whether there are data to be rewritten from the first data retaining area, and when there are data to be rewritten, data such that electrons are injected into the cells of the first short-lived area are written, after which the data of the first data retaining area are rewritten (step S303 to step S305).

An operation the same as that for the first data retaining area is carried out for the second data retaining area (step S306 to step S308).

Next, it is confirmed whether or not there is an error check trigger. The trigger may be, for example, the first time the flash memory management device 10 is started up, or may be when a predetermined time elapses. Also, the trigger may be at a timing when the control unit 13 is not carrying out another process (step S309).

When there is a trigger, data of the first short-lived area are read and compared with the data written in step S201, and it is confirmed whether an error has occurred in the data of the first short-lived area (whether the originally written data have changed). Also, in the case of a NAND-type flash memory, an ECC (error checking and correction) function is commonly installed, because of which the ECC may be checked to confirm whether an error has occurred in the first short-lived area (step S310).

When an error has occurred, data such that electrons are injected into the cells of the first short-lived area are written, after which the data of the first data retaining area are refreshed (read and written) (step S311 to step S313).

An operation the same as that for the first data retaining area is carried out for the second data retaining area (step S314 to step S317).

In the present embodiment, a description has been given of a case wherein the flash memory 11 has two data retaining areas, those being the first data retaining area and the second data retaining area, but the number of data retaining areas need not be two, and there is no problem with there being one, or more than two, data retaining areas.

Also, in the present embodiment, a description is given of a case wherein the control unit 13 is disposed in the exterior of the flash memory 11, but the present functions may also be executed by the control unit 13 and the flash memory 11 being incorporated in a control circuit (not shown).

As heretofore described, the flash memory management device 10 according to the first embodiment is such that a lifespan of a data retaining area is detected from data of a short-lived area, and the data can be refreshed, meaning that an increase in a flash memory lifespan is achieved using a simple process, while restricting an increase in cost.

Also, by providing a short-lived area wherein the number of rewrites is greater than that of a data retaining area, a lifespan decreases with the same cell structure, and a short-lived area for detecting a lifespan can be provided.

Also, by configuring a short-lived area with a multiple of cells, an effect of a variation in lifespan among cells can be restricted.

Furthermore, when rewriting data of a data retaining area, a short-lived area is rewritten prior to the data retaining area, whereby the lifespan of the short-lived area can be rendered shorter than the lifespan of the data retaining area, and the lifespan of the data retaining area can be detected more accurately.

Provided that the data storing DRAM 12 is included, the control unit 13 transfers data from a data retaining area to the DRAM 12, and data of a short-lived area are confirmed after the transfer of data to the DRAM 12, a refresh can be carried out in an idle time of the control unit 13 when the control unit 13 executes a program from the DRAM 12.

### Second Embodiment

Next, a flash memory management device and a flash memory management method according to a second embodiment will be described.

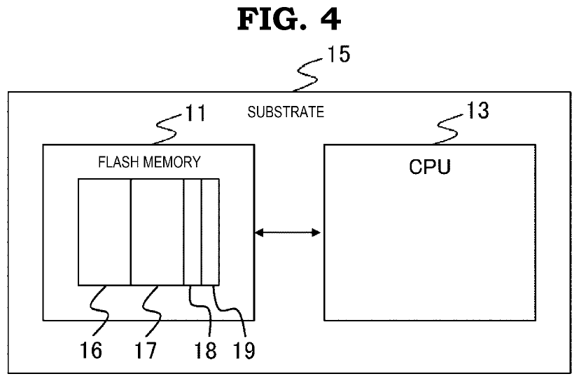

FIG. 4 is a drawing illustrating a disposition of the flash memory 11 and the control unit 13 of the flash memory management device 10 according to the second embodiment. As other configurations of the flash memory management device 10, and the flash memory management method, are the same as in the first embodiment, a description will be omitted.

The flash memory 11 and the control unit 13 of the flash memory management device 10 according to the second embodiment are mounted on a substrate 15. The flash memory 11 has a first data retaining area 16, a second data retaining area 17, a first short-lived area 18, and a second short-lived area 19. The data retaining areas of the flash memory 11 shown in FIG. 4 are one example, and the number of data retaining areas, not needing to be two, may be more than two.

Power consumption of the control unit 13 is commonly high, and heat generation is high, because of which the generated heat spreads into the substrate 15 radially, centered on the control unit 13. The first short-lived area 18 is disposed on a side nearer than the first data retaining area 16 to the control unit 13, and the second short-lived area 19 is disposed on a side nearer than the second data retaining area 17 to the control unit 13. Because of this, a temperature of the first short-lived area 18 is higher than a temperature of the first data retaining area 16, and a temperature of the second short-lived area 19 is higher than a temperature of the second data retaining area 17.

Because of this, a data retention time of the first short-lived area 18 is shorter than a data retention time of the first data retaining area 16, and a necessity or otherwise of refreshing the first data retaining area 16 can be determined by checking for an error of the first short-lived area 18. Also, a data retention time of the second short-lived area 19 is shorter than a data retention time of the second data retaining area 17, and a necessity or otherwise of refreshing the second data retaining area 17 can be determined by checking for an error of the second short-lived area 19.

In this way, the flash memory management device 10 according to the second embodiment has at least two data retaining areas whose rewrite timings differ, and a first short-lived area corresponding to a first data retaining area and a second short-lived area corresponding to a second data retaining area as short-lived areas, and the control unit 13 rewrites the first short-lived area when rewriting the first data retaining area, and rewrites the second short-lived area when rewriting the second data retaining area. Because of this, a more accurate lifespan can be detected.

Although the present application is described above in terms of various exemplary embodiments, it should be understood that the various features, aspects, and functionality described in one or more of the individual embodiments are not limited in their applicability to the particular embodiment with which they are described, but instead can be applied, alone or in various combinations, to one or more of the embodiments.

It is therefore understood that numerous modifications which have not been exemplified can be devised without departing from the scope of the present application. For example, at least one constituent components may be modified, added, or eliminated. At least one of the constituent components mentioned in at least one of the preferred embodiments may be selected and combined with the constituent components mentioned in another preferred embodiment.

### REFERENCE SIGNS LIST

10 flash memory management device, 11 flash memory, 12 DRAM, 13 control unit, 14 communication unit, 15 substrate, 16 first data retaining area, 17 second data retaining area, 18 first short-lived area, 19 second short-lived area.

1. A flash memory management device, comprising:
a flash memory used as a data retaining device; and
a controller that manages the flash memory, wherein
the flash memory has data retaining areas, which retain data, and short-lived areas, which have the same cell structure as the data retaining areas and data retaining properties inferior to those of the data retaining areas, and
the controller confirms data of the short-lived areas, and refreshes data retained in the data retaining areas in accordance with the confirmed data of the short-lived areas.

2. The flash memory management device according to claim 1, wherein the short-lived areas whose number of rewrites is greater than that of the data retaining areas are provided.

3. The flash memory management device according to claim 1, wherein the short-lived areas are disposed in positions of a higher temperature than the data retaining areas.

4. The flash memory management device according to claim 1, wherein the short-lived areas are configured of a multiple of cells.

5. The flash memory management device according to claim 2, wherein, when rewriting data of the data retaining areas, the short-lived areas are rewritten prior to the data retaining areas.

6. The flash memory management device according to claim 5, wherein the data retaining areas include at least two data retaining areas, those being a first data retaining area and a second data retaining area, whose rewrite timings differ, the short-lived areas include a first short-lived area corresponding to the first data retaining area and a second short-lived area corresponding to the second data retaining area, and
the controller rewrites the first short-lived area when rewriting the first data retaining area, and rewrites the second short-lived area when rewriting the second data retaining area.

7. The flash memory management device according to claim 5, comprising a data storing RAM, wherein
the controller transfers data from the data retaining areas to the RAM, and subsequently confirms data of the short-lived areas.

8. A flash memory management method that manages a flash memory having data retaining areas, which retain data, and short-lived areas, which have the same cell structure as the data retaining areas and data retaining properties inferior to those of the data retaining areas, wherein data of the short-lived areas are confirmed by a controller, and data of the data retaining areas are refreshed in accordance with the confirmed data of the short-lived areas.

9. The flash memory management device according to claim 2, wherein the short-lived areas are configured of a multiple of cells.

10. The flash memory management device according to claim 3, wherein the short-lived areas are configured of a multiple of cells.

11. The flash memory management device according to claim 3, wherein, when rewriting data of the data retaining areas, the short-lived areas are rewritten prior to the data retaining areas.

12. The flash memory management device according to claim 4, wherein, when rewriting data of the data retaining areas, the short-lived areas are rewritten prior to the data retaining areas.

13. The flash memory management device according to claim 9, wherein, when rewriting data of the data retaining areas, the short-lived areas are rewritten prior to the data retaining areas.

14. The flash memory management device according to claim 10, wherein, when rewriting data of the data retaining areas, the short-lived areas are rewritten prior to the data retaining areas.

15. The flash memory management device according to claim 11, wherein the data retaining areas include at least two data retaining areas, those being a first data retaining area and a second data retaining area, whose rewrite timings differ, the short-lived areas include a first short-lived area corresponding to the first data retaining area and a second short-lived area corresponding to the second data retaining area, and
the controller rewrites the first short-lived area when rewriting the first data retaining area, and rewrites the second short-lived area when rewriting the second data retaining area.

16. The flash memory management device according to claim 12, wherein the data retaining areas include at least two data retaining areas, those being a first data retaining area and a second data retaining area, whose rewrite timings differ, the short-lived areas include a first short-lived area corresponding to the first data retaining area and a second short-lived area corresponding to the second data retaining area, and
the controller rewrites the first short-lived area when rewriting the first data retaining area, and rewrites the second short-lived area when rewriting the second data retaining area.

17. The flash memory management device according to claim 13, wherein the data retaining areas include at least two data retaining areas, those being a first data retaining area and a second data retaining area, whose rewrite timings differ, the short-lived areas include a first short-lived area corresponding to the first data retaining area and a second short-lived area corresponding to the second data retaining area, and
the controller rewrites the first short-lived area when rewriting the first data retaining area, and rewrites the second short-lived area when rewriting the second data retaining area.

18. The flash memory management device according to claim 14, wherein the data retaining areas include at least two data retaining areas, those being a first data retaining area and a second data retaining area, whose rewrite timings differ, the short-lived areas include a first short-lived area corresponding to the first data retaining area and a second short-lived area corresponding to the second data retaining area, and
the controller rewrites the first short-lived area when rewriting the first data retaining area, and rewrites the second short-lived area when rewriting the second data retaining area.

19. The flash memory management device according to claim 11, comprising a data storing RAM, wherein
the controller transfers data from the data retaining areas to the RAM, and subsequently confirms data of the short-lived areas.

20. The flash memory management device according to claim 12, comprising a data storing RAM, wherein
the controller transfers data from the data retaining areas to the RAM, and subsequently confirms data of the short-lived areas.
